(19) United States
(12) Patent Application Publication
(10) Pub. No.: US 2014/0096812 A1
(43) Pub. Date: Apr. 10, 2014

(54) SOLAR SPECTRUM PANEL

(71) Applicant: Shamel A. Bersiek, Laguna Hills, CA (US)

(72) Inventor: Shamel A. Bersiek, Laguna Hills, CA (US)

(21) Appl. No.: 14/002,069

(22) PCT Filed: Feb. 23, 2011
(86) PCT No.: PCT/US11/25930

§ 371 Date: Nov. 20, 2013

Related U.S. Application Data
(60) Provisional application No. 61/308,776, filed on Feb. 26, 2010.

(51) Int. Cl. H01L 31/052

(52) U.S. Cl. CPC H01L 31/0524
USPC 136/246; 136/259

(57) ABSTRACT

An approach and device for generating electrical power from solar panels where electromagnetic radiation is filtered and concentrated at solar cells mounted on lightweight material that allows the dissipation of heat.

### CROSS-REFERENCE TO RELATED APPLICATIONS

This application claims priority of U.S. Provisional Patent Application Ser. No. 61/308,776, filed on Feb. 26, 2010, titled SOLAR SPECTRUM PANEL, which application is incorporated by reference in this application in its entirety.

### BACKGROUND

1. Field of the Invention

The present invention generally relates to a power generation device and more specifically to power generation from solar energy.

2. Related Art

There is an increase in the popularity for using solar panels for generation of electrical power. Increasing electrical power demands are overloading many national and international electrical power grids, along with the fact that power generation is a major contributor to green house gases; the construction of solar power generation stations is being actively promoted. Unfortunately, traditional solar panels are expensive, inefficient, heavy, and occupy a considerable amount of space.

Traditional solar panels typically use Silicon and Gallium Arsenate type solar cells that are coupled together within a solar panel. The basic designs of such solar cells have followed the same principals and have similar power generation efficiency results. The traditional solar cells and panels capture solar waves directly or through a magnifying lens located at the center of the solar cell. Since the electrical power generated is proportional to the sun light intensity and frequency, the power production from solar cells is proportional to the sun light's strength, wavelength exposure and angle of attack. Further, the efficiency of traditional solar cells and panels decrease as the temperature of the solar cells increase.

One of the limitations of traditional solar panel approaches is the high temperature exposure. In other words, the more sun light or electromagnetic radiation that hits the solar panel the hotter the solar cells may become. As the heat in the solar panels increases, the energy generated by the solar cells and panels is reduced.

Therefore, it would be useful to produce power from the sun with a small footprint solar panel that may produce two to five times the power occupying the same space as traditional solar panels while reducing the heat generated relative to traditional approaches.

### SUMMARY

In view of the above, an approach for a solar spectrum panel that may include a housing, wavelength filters, lens concentrator, and solar cells that are assembled on a non-conducting, heat transferring panel or plate that maximizes solar rays (electromagnetic radiation) capturing at solar cells and at the same time reduces the temperature and the total weight of the solar panel assembly is described. Electromagnetic radiation may be filtered prior to reaching the solar cells in a solar panel to reduce heat build up. The passing electromagnetic radiation may also be focused or concentrated on the solar cells, increasing the efficiency of the solar cells. The solar cells may also be placed on a lightweight plate or other structure that aids in the dissipation of heat while reducing the overall weight of the solar panel.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

The description below may be better understood by referring to the following figures. The components in the figures are not necessarily to scale, emphasis instead being placed upon illustrating the principles of the invention. In the figures, like reference numerals designate corresponding parts throughout the different views.

FIG. 1 is a perspective and diagrammatical cut side view of an example embodiment of the silicon solar spectrum panel in accordance with the present invention.

FIG. 2 is a perspective and diagrammatical view of an embodiment of the Silicon type solar panel without lenses zoomed into one section in accordance with the present invention.

FIG. 3 is a perspective and diagrammatical view of an example embodiment of the

Silicon spectrum panel of FIG. 1 without a concentrator in accordance with the present invention.

FIG. 4 is a perspective and diagrammatical view of an example Gallium spectrum solar panel with lens and filters embodiment in accordance with the present invention.

FIG. 5 is a cross sectional diagrammatical view of the Gallium spectrum solar panel example embodiment of FIG. 4 in accordance with the present invention.

FIG. 6 is a top diagrammatical view of the Gallium spectrum solar panel example embodiment of FIG. 4 in accordance with the present invention.

FIG. 7 is a perspective and diagrammatical view of a portion of the Gallium spectrum solar panel example embodiment of FIG. 4 in accordance with the present invention.

FIG. 8 is a diagrammatical view of an example embodiment of a Gallium spectrum solar panel with reflectors and lens in accordance with the present invention.

FIG. 9 is a diagrammatical view of the example Gallium spectrum panel of FIG. 8 with a bandpass filter, reflectors and with the addition of lenses in accordance with the present invention.

FIG. 10 is a diagrammatical view of an example Gallium spectrum panel embodiment with total cover bandpass filter, reflectors and with the addition of lenses in accordance with the present invention.

FIG. 11 is a diagrammatical view of the example embodiment of Gallium spectrum panel with concentrated bandpass filter, reflectors and with the addition of lenses in accordance with the present invention.

### DETAILED DESCRIPTION

It is to be understood that the following description of example implementations is given only for the purpose of illustration and is not to be taken in a limiting sense. The partitioning of examples in function blocks, modules or units shown in the drawings is not to be construed as indicating that these function blocks, modules or units are necessarily implemented as physically separate units. Functional blocks, modules or units shown or described may be implemented as separate units, circuits, chips, functions, modules, or circuit elements. One or more functional blocks or units may also be implemented in a common circuit, chip, circuit element or unit.

The present invention discloses filtration of undesired wavelengths of electromagnetic radiation that contribute to heat in solar cells and solar panels while having minimal effect on the production of electrical energy. In addition to filtration of undesired wavelengths, a wavelength concentrator is disclosed that passes and concentrates desired wavelengths through concentrators and lenses to increase the intensity and effectiveness of the desired wavelengths.

Common photocell material, such as Silicon or Gallium Arsenate may be employed to create a solar cell. Improved solar cells may also utilize or be made with Indium Phosphate as one of the materials and may result in solar cells superior to Silicon or Gallium Arsenate. Indium Phosphate is a material that has properties that promotes conductivity under certain parameters such as solar and electromagnetic waves.

The back plate of a solar panel may be made of plastic material as with traditional solar cells or with an anodized metal, such as Aluminum. The anodizing process may eliminate the electrical conducting properties of the Aluminum and allows the solar cells to be mounted directly on the metal. By mounting the solar cells directly on the light weight metal, such as Aluminum, solar panels become easier to construct, because the panels may be lighter and stronger than solar cells with traditional plastic back plate. Further, Aluminum is unique among metals in that, in addition to the thin barrier oxide, anodizing aluminum alloys in certain acidic electrolytes produce a thick oxide coating, containing a high density of microscopic pores that increase its' electrical insulation properties.

The solar panel construction may be adapted to any wavelength within an acceptable band gap of the material employed in the solar cell. The solar panel may be designed with wavelength filters to filter unwanted wavelengths at the same time pass desired wavelengths. The solar panel may also have lenses and concentrators that concentrate desired wavelengths at the solar cells within the solar panel. The solar cells may be mounted on an anodized metal back plate which acts as a heat sink and is rigid enough to allow the construction of thin and light weight solar panels.

An example deployment of a solar cell contained in a solar panel may include combining multiple solar panels to create a solar farm with one or more grids that generate large scale power in the range from a few Kilowatts to several Megawatts of electrical power or electricity. In other implementation, generation of electrical power for residential or commercial building may be provide by a solar farm in ranges that may be from one Kilowatt to a few Megawatts. Another example of deployment is generating electrical power or electricity for vehicles, such as sea vessels, planes and/or any moving vehicle, by providing electrical power from a few watts to Kilowatt range. Nevertheless, this invention is not limited to reception of solar rays but may be used with any electromagnetic radiation or light source with the desired wavelengths that may produce electrical power.

The electrical power generated by the solar cells may be sent to the electrical grid, power a building, power an electric or hybrid vehicle. The disclosed approach utilizes electromagnetic radiation wave filters and optical concentrators. The filters filter undesired wavelengths of electromagnetic radiation that are not effective in producing energy results and contribute to heat in a solar panel. By reducing the heat in the solar panel, an increase in electrical power generation efficiency is achieved. In addition to filtration, wavelength concentrators may also be employed that passes and concentrates desired wavelengths through lenses that increase the intensity of desired electromagnetic radiation at the solar cells. Such an approach of filtering and concentrating electromagnetic radiation may be applied to any solar cell material.

The solar panel structure and back plate may be made with plastic material or with an anodized metal or a metal treated with a process similar to anodizing, such as aluminum and/or aluminum that is processed with a plasma electrolytic oxidation treatment (also referred to as microarc oxidation which is similar to anodizing), such as aluminum. The anodizing or microarc oxidation of some metals result in the electrical conducting properties of the metal (aluminum in the current example) to be eliminated, thus enabling the solar cells to be mounted directly on the metal for better heat dissipation. The use of anodized aluminum also allows the construction of solar panels that are stronger and of lighter weight when compared to traditional solar panels. Aluminum is also unique among metals in that, in addition to the thin barrier oxide, anodizing aluminum alloys in certain acidic electrolytes containing chromic acid or sulfuric acid (additional material such as tin salts, surfactants and chloride ions may be additives to the acid) produces a thick oxide coating, containing a high density of microscopic pores. This coating not only acts as an electrical insulation, but also helps in corrosion prevention.

The electromagnetic wavelength spectrum, temperature, and the cell material band gap (i.e. the wavelengths the material is capable of accepting the protons in order to produce energy) are the main characteristics that affect the efficiency of a solar cell. The solar panel may be designed for any wavelength within the acceptable band gap of the material employed in the solar cell. The solar panel may have wavelength filters that filter unwanted electromagnetic wavelengths at the same time allowing desired electromagnetic wavelengths to pass. The panel may also employ lens concentrators which concentrate the filtered and desired electromagnetic radiation at the cell.

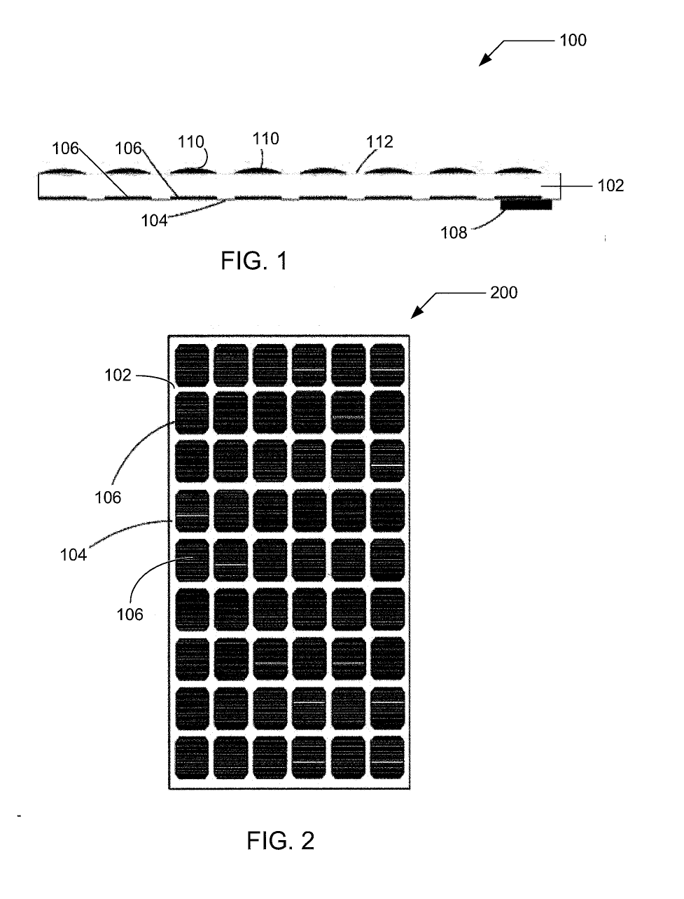

Thus, the disclosed approach for a solar spectrum panel may include a housing, wavelength falterers, lens concentrator, and solar cells that are assembled on an anodized metal panel or plate to maximize solar rays (electromagnetic radiation) capturing effectively and at the same time reducing the temperature and the total weight of the solar panel assembly as shown in FIGS. 1, 5 and 8. The benefits of disclosed approach include price competitiveness with existing solar panels, operation in a wide range of temperature and climates, and greater efficiency than existing solar panels of similar physical size and weight.

The spectrum of electromagnetic radiation striking the Earth's atmosphere is 100 to 10⁶ nanometers (nm). This can be divided into five regions in increasing order of wavelengths:
Ultraviolet C or (UVC) range, which spans a range of 100 to 280 nm. The term ultraviolet refers to the fact that the radiation is at higher frequency than violet light (and, hence also invisible to the human eye). Owing to absorption by the atmosphere, very little reaches the Earth's surface (lithosphere). This spectrum of radiation has germicidal properties, and is used in germicidal lamps.
Ultraviolet B or (UVB) range spans 280 to 315 nm. It is also greatly absorbed by the atmosphere, and along with UVC is responsible for the photochemical leading to the production of the Ozone layer.
Ultraviolet A or (UVA) spans 315 to 400 nm It has been traditionally held as less damaging to the DNA, and hence used in tanning and PUVA therapy for psoriasis.
Visible range or light spans 400 to 700 nm. As the name suggests, it is this range that is visible to the naked eye.
Infrared range that spans 700 nm to 10⁶ nm [1 (mm)] It is responsible for an important part of the electromagnetic radiation that reaches the Earth. It is also divided into three types on the basis of wavelength:
Infrared-A: 700 nm to 1,400 nm
Infrared-B: 1,400 nm to 3,000 nm
Infrared-C: 3,000 nm to 1 mm.

The solar cells may be designed to work with portions of the total spectrum of electromagnetic radiation striking the Earth's atmosphere and surface by filtering the undesired electromagnetic radiation. For example, the filtration for the UV, infrared and/or some specific undesired wavelengths will eliminate these non-effective wavelengths that typically contribute to heat from reaching the solar cells. The solar electromagnetic radiation may be filtered to the specific cell material gap band wavelength and then magnified and concentrated at the solar cell. The material internal electrical/chemical reaction to solar radiation may be improved with the addition of Indium Phosphate. The anodized aluminum panel and back plate may function as a heat sink and help the rigidity of the solar panel structure which enables the solar panel to be thin and light weight.

For example the Silicon solar cell is most effective in producing electrical power at the center of 1.1 eV (eV=Electron Volts where One electron volt is equal to 1,239.8424121 nm). The Gallium Arsenate is most effective producing electrical power at the center of 1.42 eV. Most material capable of producing energy from electromagnetic radiation fall in between 1 eV and 2 eV. See FIGS. 2, 3, 6, and 8.

In FIG. 1, a perspective and diagrammatical cut side view 100 of an example implementation of the Silicon Solar Spectrum Panel 102 in accordance with the present invention is shown. An anodized aluminum plate 104 may have a plurality of silicon type solar cells 106 affixed to its surface. The aluminum plate 104 may be double anodized in order to make the aluminum non-conducting. In other implementations, the aluminum plate 104 may be only partially anodized in the areas that non-conductivity is desired. The solar cells 106 may be directly affixed to the aluminum plate 104 as a sub-mount assembly using silver base adhesive. The silver based adhesive promotes heat transfer between the solar cell and the anodized plate. The sub-mount assembly may also be anodized which allows the use of the anodized sub-mount assemblies as individual solar cells or mounted on larger plates or surfaces, such as a larger anodized plate.

An electrical combiner box for silicon type solar cells 108 connects each of the solar cells in the solar panel 102, the solar cells 106 may connect in series, parallel or a combination of series and parallel to achieve a desired panel voltage from the solar panel 102. Each solar cell may have an associated lens concentrator 110 formed or positioned above the silicon type solar cells 106. The lens concentrators 110 may be positioned on or above a bandpass filter 112 that is also above the silicon type solar cell. The bandpass filter 112 may be embedded in a clear glass or clear acrylic type material that is mounted on top of the solar spectrum panel 102 via elevated holders. In other implementations, it may be formed on top of a group of solar cells when the solar cells are created. In yet other implementations, the bandpass filters may be formed in glass or acrylic type material that is connected to the solar spectrum panel 102 with adhesives.

Turning to FIG. 2, a perspective and diagrammatical view 200 of an embodiment of the Silicon type solar panel 102 of FIG. 1 without lenses zoomed into one section in accordance with the present invention is shown. The anodized aluminum plate 104 of FIG. 1 has a matrix of Silicon type solar cells 106. In other implementations, other types of metal or plastic plates may be used. In yet other implementations, different arrangements and types of solar cells or sub-mount assemblies may also be used and arranged upon a plate or backing to form the solar panel 102.

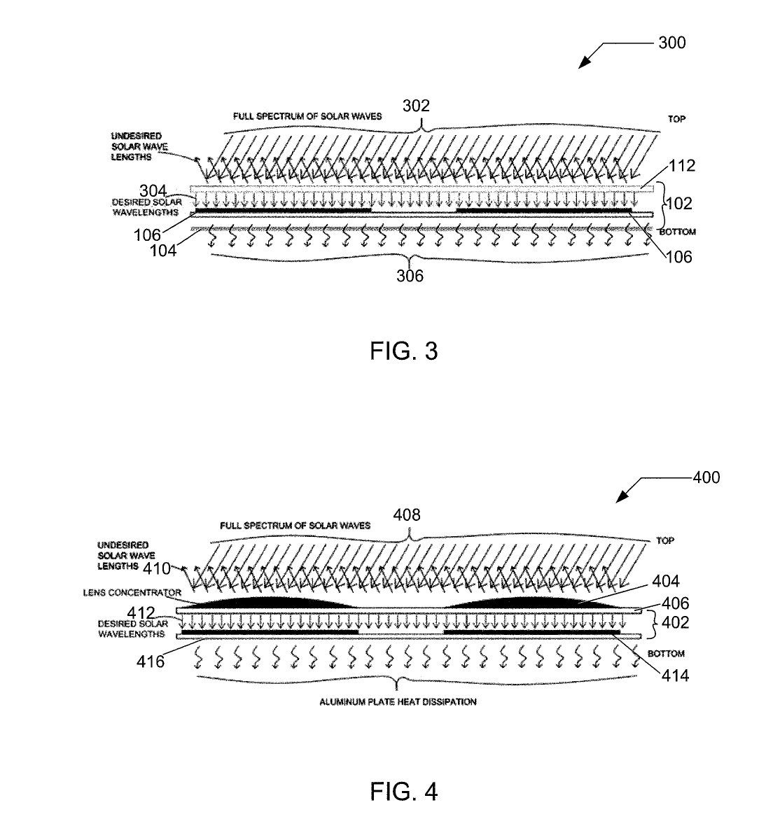

In FIG. 3, a perspective and diagrammatical view 300 of an example implementation of the Silicon spectrum panel 102 of FIG. 1 without a concentrator in accordance with the present invention is shown. Full spectrum solar waves or electromagnetic radiation 302 arrives at the solar panel 102. The bandpass filter 112 passes only the desired wavelengths of the electromagnetic radiation 304. The desired electromagnetic radiation may then be received at the solar cells 106 mounted upon the anodized aluminum plate or aluminum sub-assembly 104. The electromagnetic radiation 304 that is allowed to pass to the solar cells 106 also raises the temperature of the solar panel 102, but the anodized aluminum plate 104 dissipates a portion of that heat 306. In the current example, bandpass filtering is employed. But in other implementations, different types of filtering may be employed as long as part of the undesired solar wave lengths is filtered from striking the solar cells.

Turning to FIG. 4, a perspective and diagrammatical view 400 of an example Gallium spectrum solar panel 402 with lens concentrators 404 and bandpass filters 406 in accordance with the present invention is shown. Full spectrum electromagnetic radiation 408 arrives at the Gallium spectrum solar panel 402 and an undesired portion of the electromagnetic radiation is rejected 410 by the bandpass filter 406. The desired electromagnetic radiation 412 passes through the bandpass filters 406 and lens concentrators 404 focuses and concentrates the desired electromagnetic radiation upon the solar cells 414. Heat that builds up in the solar panel may be partially dissipated by the anodized aluminum plate 416 that acts as a heat sink.

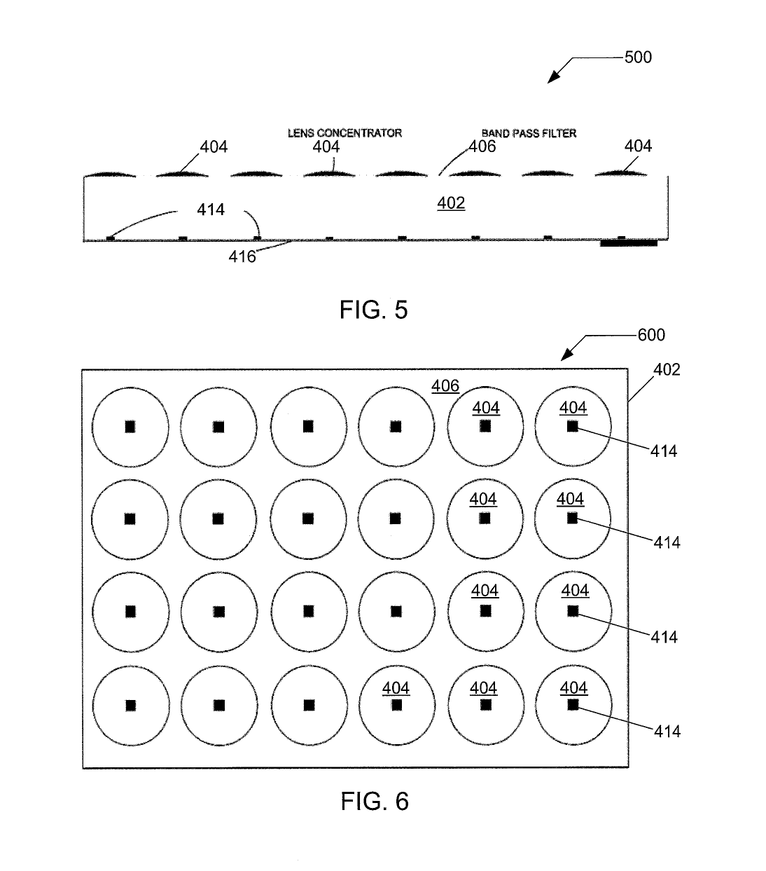

In FIG. 5, a cross sectional diagrammatical view 500 of the Gallium spectrum solar panel 402 example of FIG. 4 in accordance with the present invention is shown. A plurality of lens concentrators 404 are positioned above the bandpass filter 406. Each of the lens concentrators may have an associated Gallium type solar cell 414. The Gallium type solar cells 414 may be placed or formed upon the anodized aluminum plate 416.

Turning to FIG. 6, a top diagrammatical view 600 of the Gallium spectrum solar panel 402 example of FIG. 4 is shown. The lens concentrators 404 are shown on top of the bandpass filter 406 and located above the solar cells 414 that are located on the anodized aluminum plate. In other implementations, the lens concentrator may be of other geometric shapes other than circular lens concentrators.

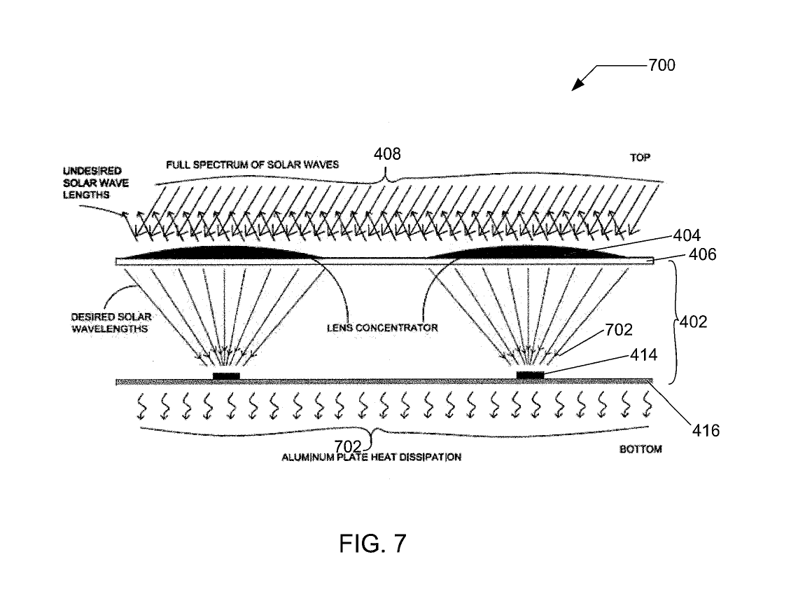

In FIG. 7, a perspective and diagrammatical view 700 of a portion of the Gallium spectrum solar panel 402 example of FIG. 4 in accordance with the present invention is shown. Once again, full spectrum solar radiation or solar waves 408 are received at the top surface of the Gallium spectrum solar panel 402. Some of the full spectrum solar radiation may pass through lens concentrators 404 prior to reaching the bandpass filter 406. In other implementations, the bandpass filter 406 may be above the lens concentrators 404. The lens concentrators 404 concentrate a portion of the electromagnetic radiation 702 that passes through the bandpass filter 406 to strike the associated Gallium type solar cells. The Gallium type solar cells 414 may be mounted or formed on the anodized aluminum plate 416. The heat that is generated by the portion of electromagnetic radiation that enterers the solar panel is partially dissipated 702 by the anodized aluminum plate 416 that acts as a heat sink. In other implementations, additional structures, such as heat pipes or fins may also be used with the anodized aluminum plate to further cool the solar panel.

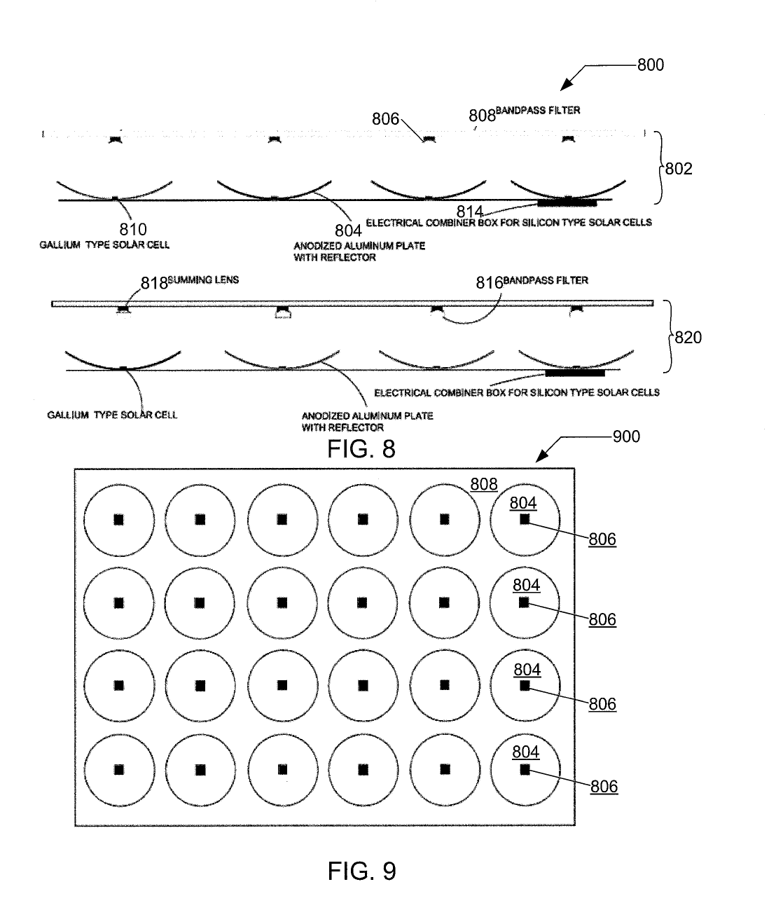

Turning to FIG. 8, a diagrammatical view 800 of an example of a Gallium spectrum solar panel 802 with reflectors 804 and summing lens 806 in accordance with the present invention is shown. A Gallium spectrum solar panel 802 may have a bandpass filter supported above solar cells 810 where the solar cells are mounted on a metal or plastic plate 812, such as anodized aluminum. Each of the solar cells 810 may be coupled to the electrical combiner box 814 if Silicon type solar cells are employed rather than Gallium of the current example. The solar cells may be arranged within a reflector that is associated with the plate 812. The reflector may be formed in the plate or in other implementations formed above the plate 812. A summing lens is associated with each of the reflectors 804 and solar cells 810.

The summing lens 806 may be formed below a bandpass filter 808 that allows only desired ranges of electromagnetic radiation to enter the solar panel. Electromagnetic radiation is filtered by the bandpass filter and enters the solar panel. The reflector redirects the electromagnetic radiation to the summing lens that focuses the electromagnetic radiation onto the solar cell. Heat that is generated by the electromagnetic radiation is partially dissipated by the anodized aluminum plate that dissipates a portion of the heat built up in the solar panel. In other implementations, the bandpass filter 816 may be formed below the summing lens 818, as seen in solar panel 820.

In FIG. 9, a diagrammatical view 900 of the example Gallium spectrum panel 802 of FIG. 8 with a bandpass filter 808, reflectors 804 and with the addition of lenses 806 above the solar cells in accordance with the present invention is shown. The lenses 806 concentrate the electromagnetic radiation to the reflectors 804 and may be formed on or above the bandpass filter. In the current example implementation, round lenses are depicted. In other implementations, other lens geometry may be employed.

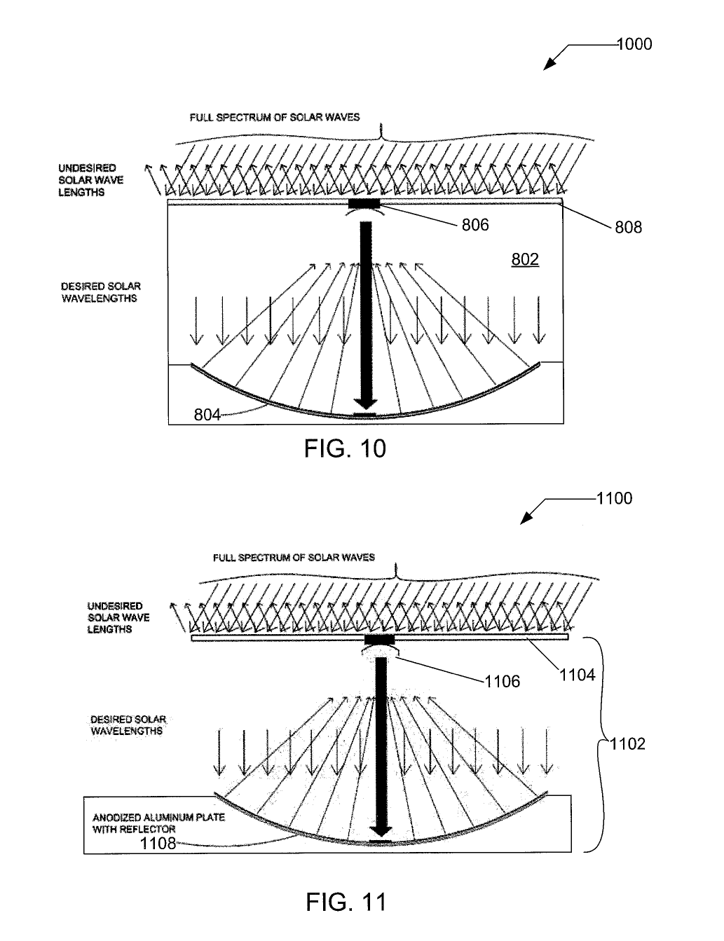

In FIG. 10, a diagrammatical view 1000 of an example Gallium spectrum panel 802 with total cover bandpass filter 808, reflectors 804 and with the addition of lenses 806 in accordance with the present invention is shown. The lenses 806 concentrate the electromagnetic radiation from the reflectors and may be formed on or above the bandpass filter 808.

In FIG. 11, a diagrammatical view 1100 of the example Gallium spectrum panel 1102 with concentrated bandpass filter 1104, reflectors 1108 and with the addition of lenses 1106 in accordance with the present invention. The lenses 1106 further concentrate the electromagnetic radiation to the reflectors and may be formed on or above the bandpass filter 1104.

The foregoing description of implementations has been presented for purposes of illustration and description. It is not exhaustive and does not limit the claimed inventions to the precise form disclosed. Modifications and variations are possible in light of the above description or may be acquired from practicing examples of the invention. The claims and their equivalents define the scope of the invention.

What is claimed is:

1. A solar cell device, comprising
a solar cell; and
a lens concentrator above the solar cell that concentrates electromagnetic radiation at the solar cell.

2. The solar cell device of claim 1, includes a filter that allows only a portion of the electromagnetic radiation to reach the solar cell.

3. The solar cell device of claim 2, where the filter is a bandpass filter.

4. The solar cell device of claim 2, were the filter is above the lens concentrator.

5. The solar cell device of claim 2, where the filter is below the lens concentrator.

6. The solar cell device of claim 1, where the solar cell is formed on a non-conducting material that dissipates heat that is built up in the solar cell device during operation.

7. The solar cell device of claim 1, where the non-conducting material is anodized aluminium.

8. The solar cell device of claim 1, where the solar cell is a Silicon type solar cell.

9. The solar cell device of claim 1, where the solar cell is a Gallium type solar cell.

10. The solar cell device of claim 1, includes a reflector that reflects the electromagnetic radiation to a summing lens that concentrates the electromagnetic radiation at the solar cell.

11. The solar cell device of claim 10, includes a bandpass filter that limits the amount of electromagnetic radiation that is concentrated at the solar cell.

12. The solar cell device of claim 11, includes a plate below the solar cell that aids in the dissipation of heat built up in the solar cell device during operation.

13. The solar cell device of claim 12, where the plate is an anodized aluminium plate.

14. A solar panel, comprising
a plurality of solar cell; and
a lens concentrator above at least one of the solar cells that concentrates electromagnetic radiation at the at least one solar cell.

15. The solar panel of claim 14, includes a filter that allows only a portion of the electromagnetic radiation to reach the at least one solar cell.

16. The solar panel of claim 15, where the filter is a bandpass filter.

17. The solar panel of claim 15, were the filter is above the lens concentrator.

18. The solar panel of claim 15, where the filter is below the lens concentrator.

19. The solar panel of claim 14, where the solar cell is formed on a non-conducting material that dissipates heat that is built up in the solar panel during operation.

20. The solar panel of claim 14, where the non-conducting material is anodized aluminium.

21. The solar panel of claim 14, where the solar cell is a Silicon type solar cell.

22. The solar cell panel of claim 14, where the solar cell is a Gallium type solar cell.

23. The solar cell panel of claim 14, includes a reflector that reflects the electromagnetic radiation to a summing lens that concentrates the electromagnetic radiation at the solar cell.

24. The solar panel of claim 10, includes a bandpass filter that limits the amount of electromagnetic radiation that is concentrated at the solar cell.

25. The solar panel of claim 11, includes a plate below the solar cell that aids in the dissipation of heat built up in the solar panel during operation.

26. The solar panel of claim 12, where the plate is an anodized aluminium plate.

27. A method of generating solar power, comprising;
receiving electromagnetic radiation at a solar panel;
concentrating the electromagnetic radiation at solar cells with the solar panel; and;
generating electrical energy from the solar cells within the solar panel.

28. The method of claim 27, includes filtering the electromagnetic radiation with a filter.

29. The method of claim 28 where the filtering is bandpass filtering of the electromagnetic radiation.

30. The method of claim 27, includes dissipating heat built up in the solar panel with a non-conducting plate that supports the solar cells.

31. The method of claim 27 where the non-conducting plate is a anodized aluminium plate.

32. The method of claim 27, includes reflecting the electromagnetic radiation within the solar panel to a summing lens with reflectors, and concentrating the electromagnetic radiation at the solar cells with the summing lens.

33. The method of claim 27 where concentrating the electromagnetic radiation includes reflecting the electromagnetic radiation within the solar panel to a summing lens with reflectors, and concentrating the electromagnetic radiation at the solar cells with the summing lens.

34. The method of claim 27, where the concentrating the electromagnetic radiation occurs with lenses.
